(19) United States
(12) Patent Application Publication
(10) Pub. No.: US 2016/0095225 A1
(43) Pub. Date: Mar. 31, 2016

(54) INDUCTOR SYSTEM FOR MULTI-PHASE POWER MANAGEMENT INTEGRATED CIRCUITS

(71) Applicant: QUALCOMM Incorporated, San Diego, CA (US)

(72) Inventors: Siamak FAZELPOUR, San Diego, CA (US); Mario Francisco VELEZ, San Diego, CA (US); Jiantao ZHENG, San Diego, CA (US)

(21) Appl. No.: 14/497,942

(22) Filed: Sep. 26, 2014

(51) Int. Cl. H05K 1/18; H01L 25/065; H05K 3/30; H01L 23/498; H01L 21/56; H01L 23/31; H01L 25/00; H01L 25/18

(52) U.S. Cl. CPC H05K 1/185; H01L 25/50; H01L 25/0655; H01L 25/18; H01L 23/49838; H01L 21/56; H01L 23/3107; H05K 1/181; H05K 3/303; H05K 2201/1003

(57) ABSTRACT

A semiconductor device includes a first integrated circuit chip, a second integrated circuit chip, a coupled inductor system, and a semiconductor package. The first integrated circuit chip is connected to a substrate and configured to process digital data. The second integrated circuit chip is configured to manage power for the first integrated circuit chip. The coupled inductor system is embedded in the substrate, connected to the second integrated circuit chip, and has a first inductor configured to be magnetically coupled to a second inductor. The semiconductor package is configured to encapsulate the first integrated circuit chip and the second integrated circuit chip.

### BACKGROUND

1. Field

Aspects of this disclosure generally relate to semiconductor devices that have multi-phase power management integrated circuits (PMICs) and coupled inductor systems used by these PMICs.

2. Description of the Related Art

The reduction in feature sizes of active devices has enabled more of them to be fabricated on an integrated circuit chip to process digital data. However, the reduction in feature sizes of active devices has also not only reduced the operating voltages of these devices, but has also narrowed the degree of deviation from nominal operating voltages that these devices can tolerate. Power management integrated circuits (PMICs) function to convert external power supply voltages (e.g., conventional alternating current voltages, batteries, etc.) to voltages to be used by the active devices and to regulate these converted voltages.

For a variety of reasons, PMICs have conventionally been fabricated on chips that are separate from the chips that process digital data. Both chips are typically mounted on a printed circuit board (PCB) and connected to each other through conductive tracks, interconnects, packaging connections (e.g., bumps or pillars), pins, vias, etc. For example, because PMICs interact with voltages at higher levels, conductors within PMICs are usually thicker than conductors within a processor chip. Additionally, PMIC designs typically include passive components, which consume a relatively substantial amount of area and are not able to enjoy a same degree of reduction in feature sizes as do active devices. Furthermore, inductive passive devices produce magnetic fields that can cause problems associated with undesired magnetic coupling and interference with the operation of active devices. These factors and others have presented obstacles to incorporating PMICs into processor chips.

Unfortunately, in addition to the limitations in further system integration that could be realized by incorporating PMIC functions into processor chips, having PMICs fabricated separate from processor chips also presents other problems. Because the regulated voltages produced by PMICs must traverse the conductive tracks, interconnects, packaging connections (e.g., bumps or pillars), pins, vias, etc. to be conducted to the processor chips, losses due to the impedance of these interconnects can reduce the levels of the voltages ultimately conducted to the processor chips making it difficult for the PMICs to regulate the voltages provided to the processor chips. Increasing the levels of the voltages produced by the PMICs is of limited value as a solution not only because of the increase in power consumption, but also because of variations in the impedance of the interconnects under different conditions. Additionally, the process of traversing the interconnects can lead to the introduction of noise into the voltage that is conducted to the processor chips. Decoupling capacitors are of limited value in countering this problem. Furthermore, parasitic inductance associated with traversing the interconnects can interfere with power supply voltages for the PCBs. Moreover, the distances between the PMICs and the processor chips can reduce the response time of the PMICs to transients that develop that effect the processor chips.

### SUMMARY

Features and utilities of the disclosure can be achieved by providing a semiconductor device that can include a first integrated circuit chip, a second integrated circuit chip, a coupled inductor system, and a semiconductor package. The first integrated circuit chip can be connected to a first surface of a substrate and can be configured to process digital data. The second integrated circuit chip can be configured to manage a power for the first integrated circuit chip. The coupled inductor system can be embedded in the substrate, can be connected to the second integrated circuit chip, and can have a first inductor configured to be magnetically coupled to a second inductor. The semiconductor package can be configured to encapsulate the first integrated circuit chip.

In an aspect, the second integrated circuit chip can be connected to a second surface of the substrate. Optionally, a third integrated circuit chip can be connected to a printed circuit board and can be configured to manage the power for the first integrated circuit chip at a first stage and the second integrated circuit chip can be configured to manage the power for the first integrated circuit chip at a second stage.

In an aspect, the second integrated circuit chip can be connected to the first surface of the substrate and the semiconductor package can be configured to encapsulate the second integrated circuit. Optionally, the semiconductor device can be connected to a printed circuit board, a third integrated circuit chip can be connected to the printed circuit board and can be configured to manage the power for the first integrated circuit chip at a first stage, and the second integrated circuit chip can be configured to manage the power for the first integrated circuit chip at a second stage.

Optionally, the coupled inductor system can be a planar inductor system.

Optionally, the coupled inductor system can be a solenoid inductor system.

The coupled inductor system can have a specific value of inductance and can be configured to have, during a steady state operation of the semiconductor device, a higher value of effective inductance than an inductor system having at least one uncoupled inductor with the specific value of inductance and configured in the semiconductor device in a same manner as the coupled inductor system.

The coupled inductor system can have a specific value of inductance and can be configured to have, during a transient operation of the semiconductor device, a lower value of effective inductance and a higher derivative of current with respect to time than an inductor system that has at least one uncoupled inductor with the specific value of inductance and is configured in the semiconductor device in a same manner as the coupled inductor system.

Features and utilities of the disclosure can also be achieved by providing a semiconductor device that can include a first integrated circuit chip, a second integrated circuit chip, an inductor system, and a semiconductor package. The first integrated circuit chip can be connected to a first surface of a substrate and can be configured to process digital data. The second integrated circuit chip can be connected to a second surface of the substrate and can be configured to manage a power for the first integrated circuit chip. The inductor system can be embedded in the substrate and can be connected to the second integrated circuit chip. The semiconductor package can be configured to encapsulate the first integrated circuit chip.

In an aspect, the inductor system can be a coupled inductor system and can have a first inductor configured to be magnetically coupled to a second inductor. The coupled inductor system can have a specific value of effective inductance and can be configured to have, during a steady state operation of the semiconductor device, a higher value of effective inductance than an inductor system that has at least one uncoupled inductor with the specific value of inductance and is configured in the semiconductor device in a same manner as the coupled inductor system. The coupled inductor system can have a specific value of effective inductance and can be configured to have, during a transient operation of the semiconductor device, a lower effective inductance and a higher value of a derivative of current with respect to time than an inductor system that has at least one uncoupled inductor with the specific value of inductance and is configured in the semiconductor device in a same manner as the coupled inductor system.

Optionally, the inductor system can be a planar inductor system.

Optionally, the inductor system can be a solenoid inductor system.

Optionally, the semiconductor device can be connected to a printed circuit board, a third integrated circuit chip can be connected to the printed circuit board and can be configured to manage the power for the first integrated circuit chip at a first stage, and the second integrated circuit chip can be configured to manage the power for the first integrated circuit chip at a second stage.

Features and utilities of the disclosure can also be achieved by providing a method for fabricating a semiconductor device. The method can include embedding an inductor system in a substrate. The method can also include connecting a first integrated circuit chip to a first surface of the substrate. The first integrated circuit chip can be configured to process digital data. If the inductor system has a first inductor configured to be magnetically coupled to a second inductor, then the method can also include connecting a second integrated circuit chip to the first surface or to a second surface of the substrate; otherwise, the method can also include connecting the second integrated circuit chip to the second surface. The second integrated circuit chip can be connected to the inductor system and can be configured to manage a power for the first integrated circuit chip. The method can also include forming a semiconductor package to encapsulate the first integrated circuit chip.

Optionally, if the second integrated circuit is connected to the first surface, then the forming the semiconductor package operation can include encapsulating the second integrated circuit chip.

Optionally, the method can include connecting the semiconductor device to a printed circuit board. The semiconductor device can be connected to the printed circuit board so that the second surface faces the printed circuit board.

Optionally, the method can also include connecting a third integrated circuit chip to the printed circuit board. The third integrated circuit chip can be configured to manage the power for the first integrated circuit chip at a first stage and the second integrated circuit chip can be configured to manage the power for the first integrated circuit chip at a second stage.

### BRIEF DESCRIPTION OF THE DRAWINGS

These and other sample aspects of the disclosure are described in the detailed description and the claims that follow, and in the accompanying drawings.

FIG. 1 is a diagram of an example of a conventional printed circuit board that includes a power management integrated circuit chip.

FIG. 2 includes a graph of an example of impedance as a function of frequency at a bump when the inductor is connected to the printed circuit board.

FIG. 3 is a diagram of a first example of a semiconductor device according to the disclosure.

FIG. 4 is a diagram of an example of an uncoupled planar inductor.

FIG. 5 is a diagram of an example of an uncoupled solenoid inductor.

FIG. 6 is a diagram of an example of a coupled planar inductor.

FIG. 7 is a diagram of an example of a coupled planar inductor system.

FIG. 8 includes graphs of examples of derivatives of current with respect to time for operations of the semiconductor device illustrated in FIG. 3.

FIG. 9 is a diagram of a second example of a semiconductor device according to the disclosure.

FIG. 10 includes a graph of an example of impedance as a function of frequency when the inductor is embedded in the substrate.

FIG. 11 is a chart of improvements in static noise at a bump when the inductor is embedded in the substrate.

FIG. 12 is a chart of improvements in dynamic noise at a bump the inductor is embedded in the substrate.

FIG. 13 is a flowchart of a method of fabricating a semiconductor device according to the disclosure.

In accordance with common practice, the various features illustrated in the drawings may not be drawn to scale. Accordingly, the dimensions of the various features may be arbitrarily expanded or reduced for clarity. In addition, some of the drawings may be simplified for clarity. Thus, the drawings may not depict all of the components of a given apparatus (e.g., device) or method. Finally, like reference numerals may be used to denote like features throughout the specification and figures.

### DETAILED DESCRIPTION

Aspects of this disclosure generally relate to semiconductor devices that have multi-phase power management integrated circuits (PMICs) and coupled inductor systems used by these PMICs.

The reduction in feature sizes of active devices has enabled more of them to be fabricated on an integrated circuit chip to process digital data. However, the reduction in feature sizes of active devices has also not only reduced the operating voltages of these devices, but has also narrowed the degree of deviation from nominal operating voltages that these devices can tolerate. Power management integrated circuits (PMICs) function to convert external power supply voltages (e.g., conventional alternating current voltages, batteries, etc.) to voltages to be used by the active devices and to regulate these converted voltages.

For a variety of reasons, PMICs have conventionally been fabricated on chips that are separate from the chips that process digital data. Both chips are typically mounted on a printed circuit board (PCB) and connected to each other through conductive tracks, interconnects, packaging connections (e.g., bumps or pillars), pins, vias, etc. For example, because PMICs interact with voltages at higher levels, conductors within PMICs are usually thicker than conductors within a processor chip. Additionally, PMIC designs typically include passive components, which consume a relatively substantial amount of area and are not able to enjoy a same degree of reduction in feature sizes as do active devices. Furthermore, inductive passive devices produce magnetic fields that can cause problems associated with undesired magnetic coupling and interference with the operation of active devices. These factors and others have presented obstacles to incorporating PMICs into processor chips.

Unfortunately, in addition to the limitations in further system integration that could be realized by incorporating PMIC functions into processor chips, having PMICs fabricated separate from processor chips also presents other problems. Because the regulated voltages produced by PMICs must traverse the conductive tracks, interconnects, packaging connections (e.g., bumps or pillars), pins, vias, etc. to be conducted to the processor chips, losses due to the impedance of these interconnects can reduce the levels of the voltages ultimately conducted to the processor chips making it difficult for the PMICs to regulate the voltages provided to the processor chips. Increasing the levels of the voltages produced by the PMICs is of limited value as a solution not only because of the increase in power consumption, but also because of variations in the impedance of the interconnects under different conditions. Additionally, the process of traversing the interconnects can lead to the introduction of noise into the voltage that is conducted to the processor chips. Decoupling capacitors are of limited value in countering this problem. Furthermore, parasitic inductance associated with traversing the interconnects can interfere with power supply voltages for the PCBs. Moreover, the distances between the PMICs and the processor chips can reduce the response time of the PMICs to transients that develop that effect the processor chips.

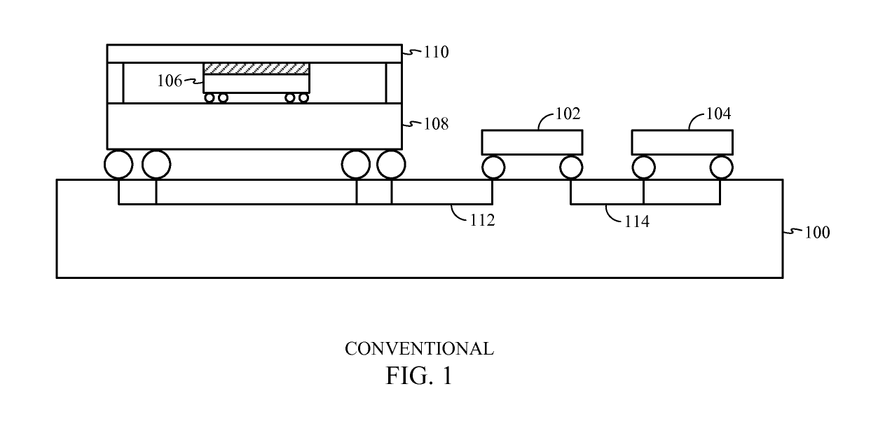

FIG. 1 is a diagram of an example of a conventional printed circuit board (PCB) 100 that includes a power management integrated circuit (PMIC) chip 102. The circuit board 100 also includes an inductor 104 and an integrated circuit chip configured to process digital data 106. The integrated circuit chip configured to process digital data 106 is connected to a substrate 108. A semiconductor package 110 is configured to encapsulate the integrated circuit chip configured to process digital data 106. First interconnects 112 connect the integrated circuit chip configured to process digital data 106 to the power management integrated circuit chip 102. Second interconnects 114 connect the to the power management integrated circuit chip 102 to the inductor 104.

The power management integrated circuit chip 102 is configured to receive a voltage from an external power supply (e.g., conventional alternating current voltages, batteries, etc.) (not illustrated) through a conductive track (not illustrated) on the printed circuit board 100, packaging connections (e.g., bumps or pillars) (not illustrated) that connect the printed circuit board 100 to the power management integrated circuit chip 102, and interconnects (not illustrated) within the power management integrated circuit chip 102. The power management integrated circuit chip 102 is configured to convert a level of voltage form the external power supply to levels of voltages to be used by active devices within the integrated circuit chip configured to process digital data 106 and to regulate these converted voltages. Optionally, the power management integrated circuit chip 102 can also perform at least one of a voltage regulation operation, a battery charging operation, a power source selection operation, a power sequencing operation, a direct current-to-direct current conversion, other functions known to those of skill in the art, or a combination of the foregoing. Each of first and second interconnects 112 and 114 includes conductive tracks, interconnects, packaging connections (e.g., bumps or pillars), pins, vias, etc.

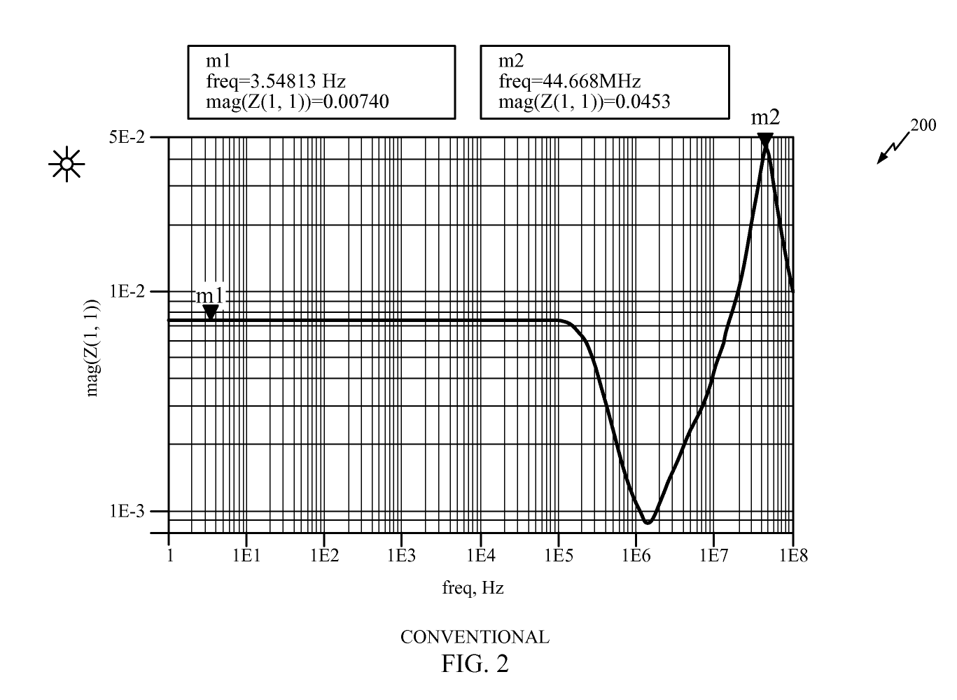

FIG. 2 includes a graph 200 of an example of impedance as a function of frequency at a bump when the inductor 104 is connected to the printed circuit board 100.

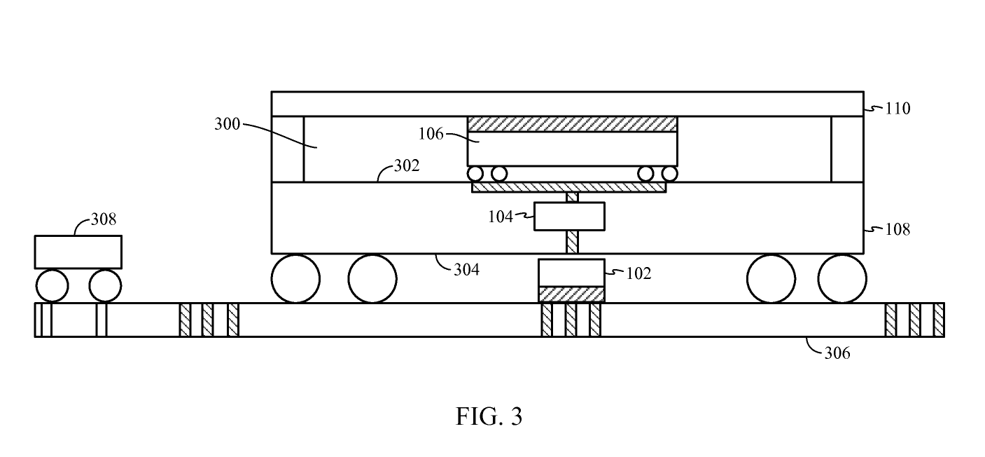

FIG. 3 is a diagram of a first example of a semiconductor device 300 according to the disclosure. The semiconductor device 300 can include the power management integrated circuit chip 102, the inductor 104, the integrated circuit chip configured to process digital data 106, the substrate 108, and the semiconductor package 110. Preferably, the power management integrated circuit chip 102 can be a multi-phase power management integrated circuit. The integrated circuit chip configured to process digital data 106 can be connected to a first surface 302 of the substrate 108. The semiconductor package 110 can be configured to encapsulate the integrated circuit chip configured to process digital data 106. The power management integrated circuit chip 102 can be connected to a second surface 304 of the substrate 108. The second surface 304 can be opposite of the first surface 302. The second surface 304 can face a printed circuit board 306 to which the semiconductor device 300 can be configured to be connected. The power management integrated circuit chip 102 can be configured to manage a power for the integrated circuit chip configured to process digital data 106. The inductor 104 can be embedded in the substrate 108 and can be connected to the power management integrated circuit chip 102.

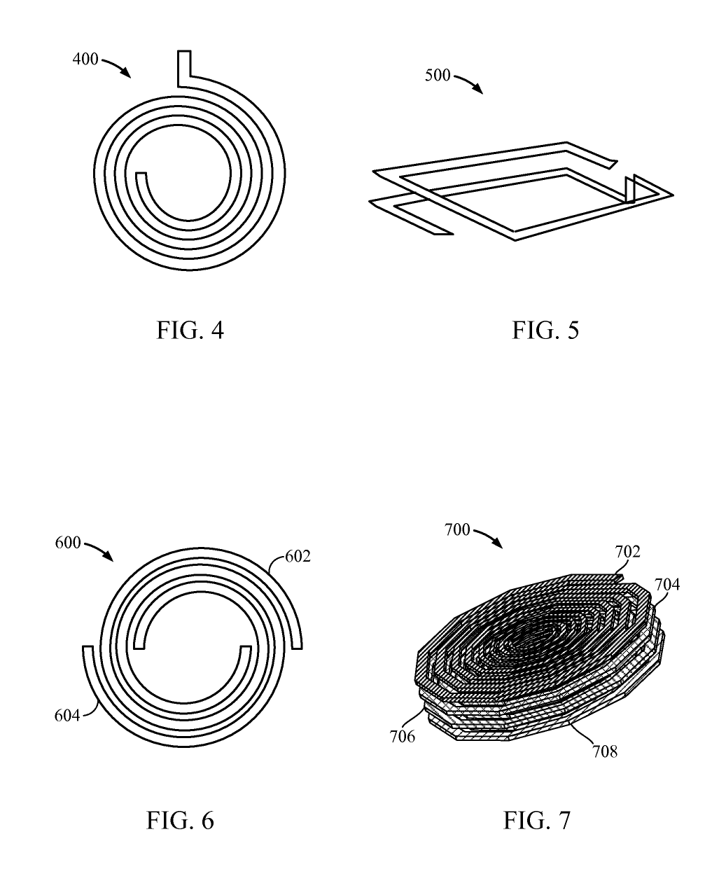

Optionally, the inductor 104 can be a planar inductor. FIG. 4 is a diagram of an example of an uncoupled planar inductor 400. Sides of the uncoupled planar inductor 400 can be straight, curved, or a combination of both.

Optionally, the inductor 104 can be a solenoid inductor. FIG. 5 is a diagram of an example of an uncoupled solenoid inductor 500. Sides of the uncoupled solenoid inductor 500 can be straight, curved or a combination of both.

Optionally, the inductor 104 can be a coupled inductor. In an implementation, the coupled inductor can have a magnetic coupling coefficient between 0.4 and 0.7. FIG. 6 is a diagram of an example of a coupled planar inductor 600. The coupled planar inductor 600 can include, for example, a first conductor 602 configured to be magnetically coupled to a second conductor 604. Sides of the coupled planar inductor 600 can be straight, curved, or a combination of both. FIG. 7 is a diagram of an example of a coupled planar inductor system 700. The coupled planar inductor system 700 can include, for example, a first inductor 702, a second inductor 704, a third inductor 706, and a fourth inductor. Each of the first inductor 702, the second inductor 704, the third inductor 706, and the fourth inductor 708 can be configured to be coupled to at least one other of the first inductor 702, the second inductor 704, the third inductor 706, and the fourth inductor 708. Sides of the coupled planar inductor system 700 can be straight, curved, or a combination of both. In an implementation, the coupled planar inductor system 700 can have an inductance of 15 nH and a diameter of 0.73 mm.

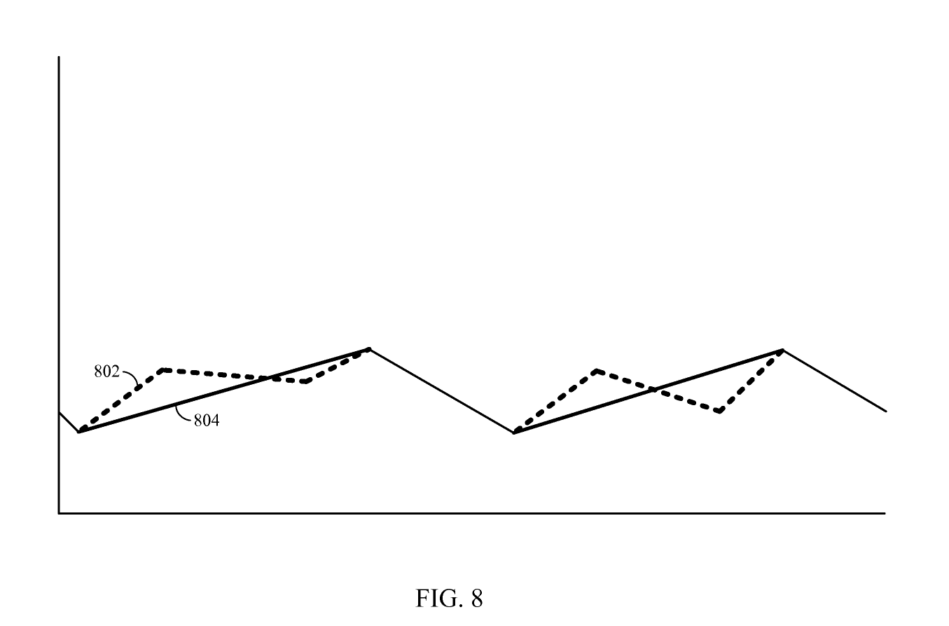

FIG. 8 includes graphs 802 and 804 of examples of derivatives of current with respect to time for operations of the semiconductor device 300. The graph 802 is for the semiconductor device 300 when the inductor 104 is a coupled inductor system. The graph 804 is for the semiconductor device 300 when the inductor 104 comprises at least one uncoupled inductor. For each of the graphs 802 and 804, the inductor 104 has the same specific value of inductance and is configured in the semiconductor device 300 in the same manner. Advantageously, when the inductor 104 is a coupled inductor system, the inductor 104 can be configured to have, during a steady state operation of the semiconductor device 300, a higher effective value of inductance than if the inductor 104 comprises at least one uncoupled inductor. This can reduce inductor ripple, reduce a switching frequency, and improve efficiency. Advantageously, when the inductor 104 is a coupled inductor system, the inductor 104 can be configured to have, during a transient operation of the semiconductor device 300, a lower effective total inductance and a higher value of the derivative of current with respect to time than if the inductor 104 comprises at least one uncoupled inductor. This can facilitate having a higher derivative of current with respect to time to respond more quickly to load changes.

Optionally, the semiconductor device 300 can be connected to the printed circuit board 306 and a third integrated circuit 308 can be connected to the printed circuit board 306. The third integrated circuit 308 can be configured to manage the power for the integrated circuit chip configured to process digital data 106 at a first stage and the power management integrated circuit chip 102 can be configured to manage the power for the integrated circuit chip configured to process digital data 106 at a second stage.

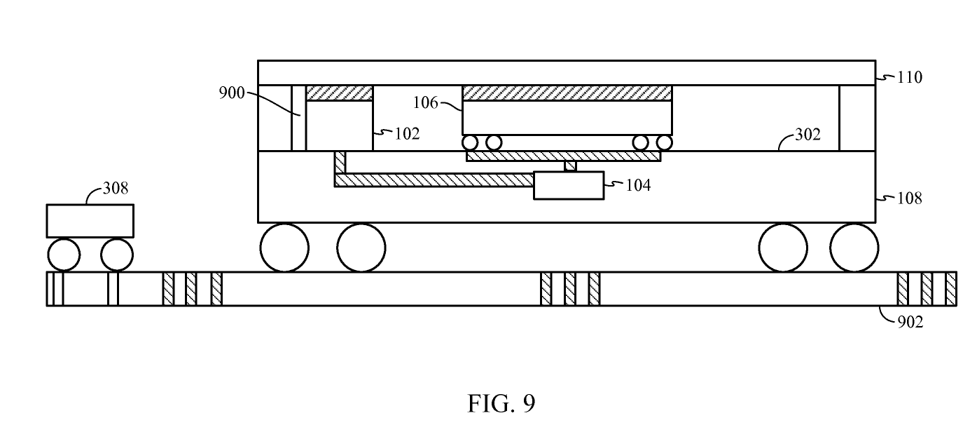

FIG. 9 is a diagram of a second example of a semiconductor device 900 according to the disclosure. The semiconductor device 900 can include the power management integrated circuit chip 102, the inductor 104, the integrated circuit chip configured to process digital data 106, the substrate 108, and the semiconductor package 110. Preferably, the power management integrated circuit chip 102 can be a multi-phase power management integrated circuit. The integrated circuit chip configured to process digital data 106 can be connected to the first surface 302 of the substrate 108. The power management integrated circuit chip 102 can be connected to the first surface 302 of the substrate 108. The semiconductor package 110 can be configured to encapsulate the integrated circuit chip configured to process digital data 106 and the power management integrated circuit chip 102. The power management integrated circuit chip 102 can be configured to manage the power for the integrated circuit chip configured to process digital data 106. The inductor 104 can be embedded in the substrate 108 and can be connected to the power management integrated circuit chip 102. The inductor 104 can be a coupled inductor system. In an implementation, the coupled inductor system can have a magnetic coupling coefficient between 0.4 and 0.7.

Optionally, the inductor 104 can be a planar inductor. FIG. 6 is a diagram of an example of a coupled planar inductor 600. The coupled planar inductor 600 can include, for example, the first conductor 602 configured to be magnetically coupled to the second conductor 604. The sides of the coupled planar inductor 600 can be straight, curved, or a combination of both. Optionally, the inductor 104 can be a planar inductor system. FIG. 7 is a diagram of an example of a coupled planar inductor system 700. The coupled planar inductor system 700 can include, for example, the first inductor 702, the second inductor 704, the third inductor 706, and the fourth inductor. Each of the first inductor 702, the second inductor 704, the third inductor 706, and the fourth inductor 708 can be configured to be coupled to at least one other of the first inductor 702, the second inductor 704, the third inductor 706, and the fourth inductor 708. The sides of the coupled planar inductor system 700 can be straight, curved, or a combination of both. In an implementation, the coupled planar inductor system 700 can have an inductance of 15 nH and a diameter of 0.73 mm.

FIG. 8 includes the graphs 802 and 804 of examples of derivatives of current with respect to time for operations of the semiconductor device 900. The graph 802 is for the semiconductor device 900 when the inductor 104 is a coupled inductor system. The graph 804 is for the semiconductor device 900 when the inductor 104 comprises at least one uncoupled inductor. For each of the graphs 802 and 804, the inductor 104 has the same specific value of inductance and is configured in the semiconductor device 900 in the same manner. Advantageously, when the inductor 104 is a coupled inductor system, the inductor 104 can be configured to have, during a steady state operation of the semiconductor device 900, a higher effective value of inductance than if the inductor 104 was at least one uncoupled inductor. This can reduce inductor ripple, reduce a switching frequency, and improve efficiency. Advantageously, when the inductor 104 is a coupled inductor system, the inductor 104 can be configured to have, during a transient operation of the semiconductor device 900, a lower effective total inductance and a higher value of the derivative of current with respect to time than if the inductor 104 comprises at least one uncoupled inductor. This can facilitate having a higher derivative of current with respect to time to respond more quickly to load changes.

Optionally, the semiconductor device 900 can be connected to the printed circuit board 902 and the third integrated circuit 308 can be connected to the printed circuit board 902. The third integrated circuit 308 can be configured to manage the power for the integrated circuit chip configured to process digital data 106 at a first stage and the power management integrated circuit chip 102 can be configured to manage the power for the integrated circuit chip configured to process digital data 106 at a second stage.

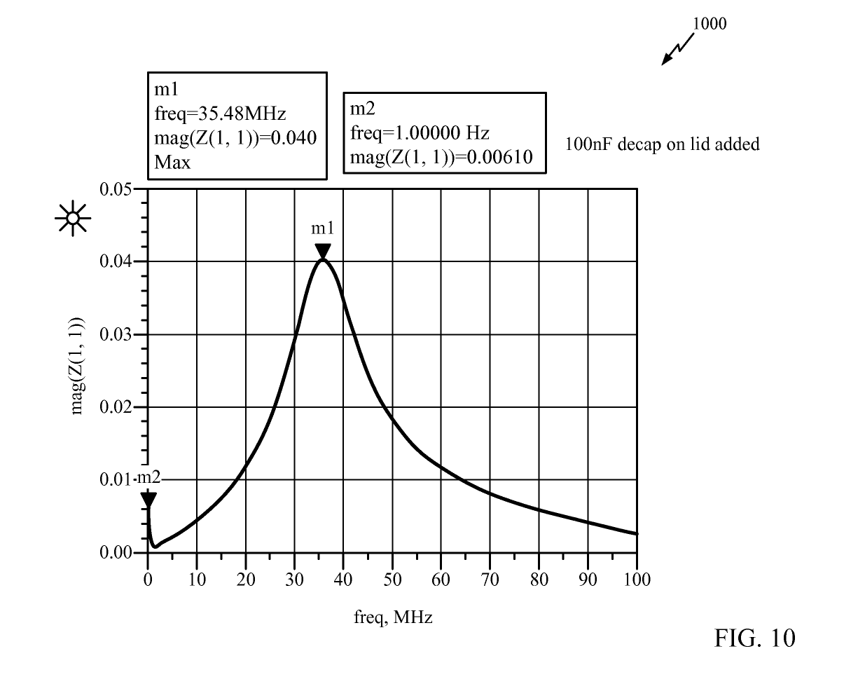

FIG. 10 includes a graph 1000 of an example of impedance as a function of frequency when the inductor 104 is embedded in the substrate 108.

The disclosure provides several advantages. For example, advantageously current ripples of the power management integrated circuit chip 102 can be drastically reduced. Advantageously, a switching frequency can be reduced from 100 MHz to 50 MHz. Advantageously, a response of the power management integrated circuit chip 102 to load changes can be significantly improved. Advantageously, efficiency can be significantly improved. Advantageously, processor noise can be reduced. Advantageously, a power pin count can be reduced significantly. Advantageously, less power is consumed. Advantageously, less area on a chip is consumed.

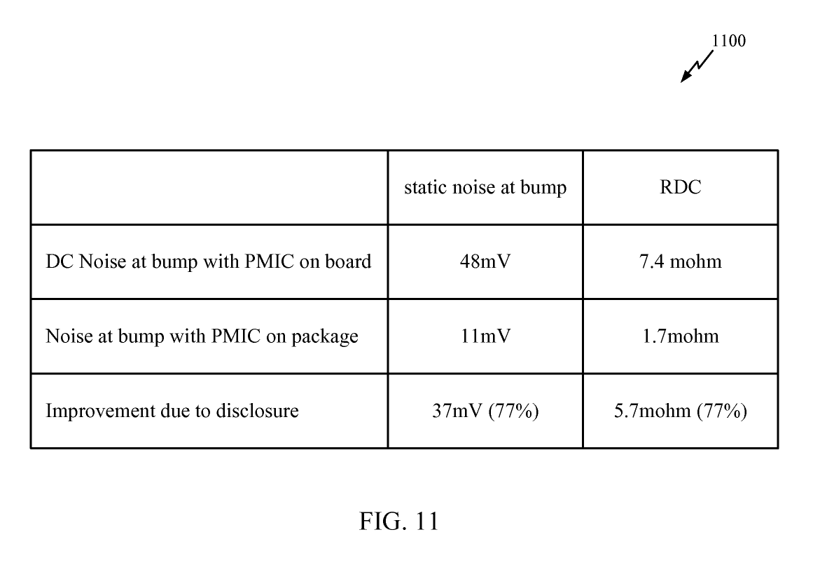

FIG. 11 is a chart 1100 of improvements in static noise at a bump when the inductor 104 is embedded in the substrate 108.

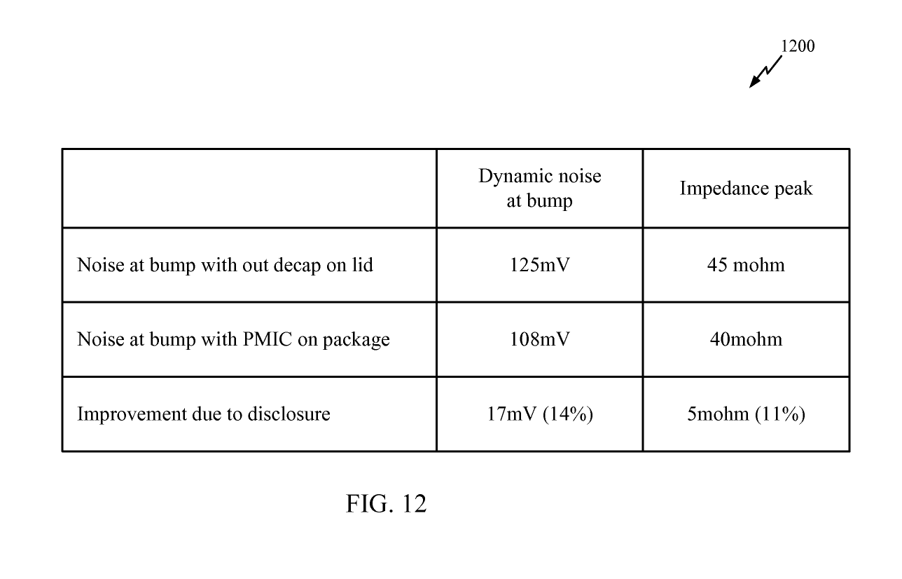

FIG. 12 is a chart 1200 of improvements in dynamic noise at a bump the inductor 104 is embedded in the substrate 108.

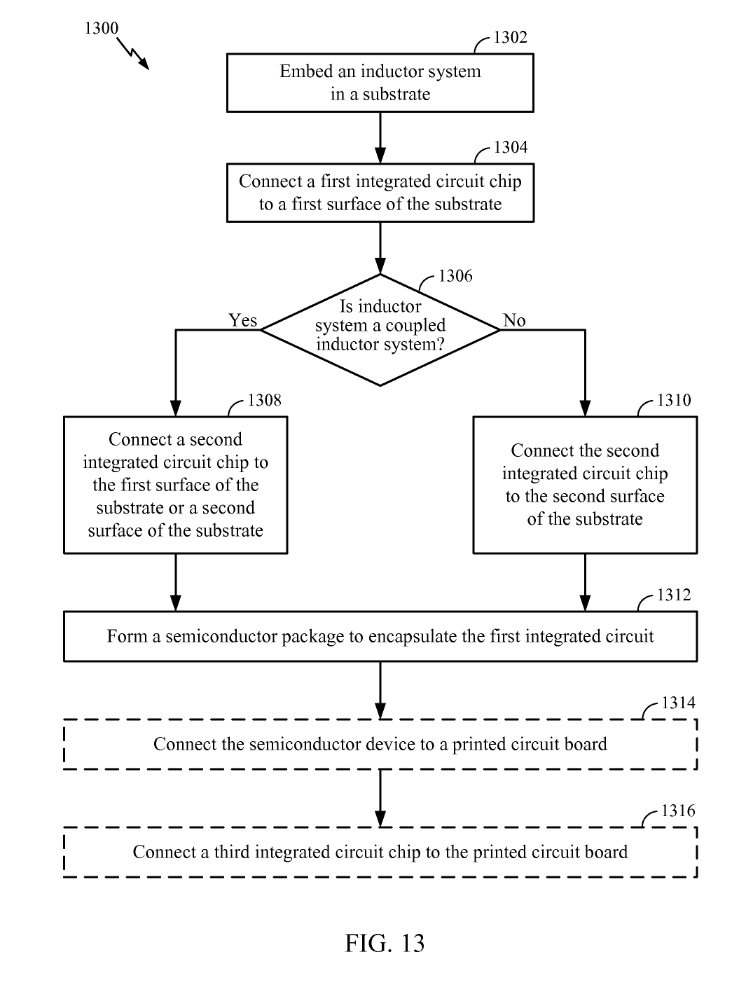

FIG. 13 is a flowchart of a method 1300 of fabricating a semiconductor device according to the disclosure. In FIG. 13, optional operations of the method 1300 are illustrated in dashed blocks.

At an operation 1302, an inductor system can be embedded in a substrate.

At an operation 1304, a first integrated circuit chip can be connected to a first surface of the substrate. The first integrated circuit chip can be configured to process digital data.

At an operation 1306, a determination is made if the inductor system has a first inductor configured to be magnetically coupled to a second inductor.

If the inductor system has a first inductor configured to be magnetically coupled to a second inductor, then at an operation 1308, a second integrated circuit chip can be connected to the first surface of the substrate or to a second surface of the substrate.

If the inductor system does not have a first inductor configured to be magnetically coupled to a second inductor, then at an operation 1310, the second integrated circuit chip can be connected to the second surface of the substrate.

The second integrated circuit chip can be connected to the inductor system and can be configured to manage a power for the first integrated circuit chip.

At an operation 1312, a semiconductor package can be formed to encapsulate the first integrated circuit chip. Optionally, if the second integrated circuit chip is connected to the first surface of the substrate, then the semiconductor package can be formed also to encapsulate the first integrated circuit chip.

Optionally, at an operation 1314, the semiconductor device can be connected to a printed circuit board. The semiconductor device can be connected to the printed circuit board so that the second surface of the substrate faces the printed circuit board.

Optionally, at an operation 1316, a third integrated circuit chip can be connected to the printed circuit board. The third integrated circuit chip can be configured to manage the power for the first integrated circuit chip at a first stage and the second integrated circuit chip can be configured to manage the power for the first integrated circuit chip at a second stage.

While the foregoing disclosure describes various illustrative aspects, it is noted that various changes and modifications may be made to the illustrated examples without departing from the scope defined by the appended claims. The present disclosure is not intended to be limited to the specifically illustrated examples alone. For example, although certain aspects may be described or claimed in the singular, the plural is contemplated unless limitation to the singular is explicitly stated.

What is claimed is:

1. A semiconductor device, comprising:
a first integrated circuit chip connected to a first surface of a substrate and configured to process digital data;
a second integrated circuit chip configured to manage a power for the first integrated circuit chip;
a coupled inductor system embedded in the substrate, connected to the second integrated circuit chip, and having a first inductor configured to be magnetically coupled to a second inductor; and
a semiconductor package configured to encapsulate the first integrated circuit chip.

2. The semiconductor device of claim 1, wherein the second integrated circuit chip is connected to a second surface of the substrate.

3. The semiconductor device of claim 2, further comprising a third integrated circuit chip connected to a printed circuit board and configured to manage the power for the first integrated circuit chip at a first stage, wherein the second integrated circuit chip is configured to manage the power for the first integrated circuit chip at a second stage.

4. The semiconductor device of claim 1, wherein the second integrated circuit chip is connected to the first surface of the substrate and the semiconductor package is configured to encapsulate the second integrated circuit.

5. The semiconductor device of claim 4, wherein the semiconductor device is connected to a printed circuit board, a third integrated circuit chip is connected to the printed circuit board and configured to manage the power for the first integrated circuit chip at a first stage, and the second integrated circuit chip is configured to manage the power for the first integrated circuit chip at a second stage.

6. The semiconductor device of claim 1, wherein the coupled inductor system is a planar inductor system.

7. The semiconductor device of claim 1, wherein the coupled inductor system is a solenoid inductor system.

8. The semiconductor device of claim 1, wherein the coupled inductor system has a specific value of inductance and is configured to have, during a steady state operation of the semiconductor device, a higher value of effective inductance than an inductor system having at least one uncoupled inductor with the specific value of inductance and configured in the semiconductor device in a same manner as the coupled inductor system.

9. The semiconductor device of claim 1, wherein the coupled inductor system has a specific value of inductance and is configured to have, during a transient operation of the semiconductor device, a lower value of effective inductance and a higher derivative of current with respect to time than an inductor system having at least one uncoupled inductor with the specific value of inductance and configured in the semiconductor device in a same manner as the coupled inductor system.

10. A semiconductor device, comprising:
a first integrated circuit chip connected to a first surface of a substrate and configured to process digital data;
a second integrated chip connected to a second surface of the substrate and configured to manage a power for the first integrated circuit chip;
an inductor system embedded in the substrate and connected to the second integrated circuit chip; and
a semiconductor package configured to encapsulate the first integrated circuit chip.

11. The semiconductor device of claim 10, wherein the inductor system is a coupled inductor system having a first inductor configured to be magnetically coupled to a second inductor.

12. The semiconductor device of claim 11, wherein the coupled inductor system has a specific value of effective inductance and is configured to have, during a steady state operation of the semiconductor device, a higher value of effective inductance than an inductor system having at least one uncoupled inductor with the specific value of inductance and configured in the semiconductor device in a same manner as the coupled inductor system.

13. The semiconductor device of claim 11, wherein the coupled inductor system has a specific value of effective inductance and is configured to have, during a transient operation of the semiconductor device, a lower effective inductance and a higher value of a derivative of current with respect to time than an inductor system having at least one uncoupled inductor with the specific value of inductance and configured in the semiconductor device in a same manner as the coupled inductor system.

14. The semiconductor device of claim 10, wherein the inductor system is a planar inductor system.

15. The semiconductor device of claim 10, wherein the inductor system is a solenoid inductor system.

16. The semiconductor device of claim 10, wherein the semiconductor device is connected to a printed circuit board, a third integrated circuit chip is connected to the printed circuit board and is configured to manage the power for the first integrated circuit chip at a first stage, and the second integrated circuit chip is configured to manage the power for the first integrated circuit chip at a second stage.

17. A method for fabricating a semiconductor device, comprising:
embedding an inductor system in a substrate;
connecting a first integrated circuit chip to a first surface of the substrate, the first integrated circuit chip configured to process digital data;
if the inductor system has a first inductor configured to be magnetically coupled to a second inductor, then connecting a second integrated circuit chip one of to the first surface or to a second surface of the substrate, otherwise connecting the second integrated circuit chip to the second surface, the second integrated circuit chip connected to the inductor system and configured to manage a power for the first integrated circuit chip; and
forming a semiconductor package to encapsulate the first integrated circuit chip.

18. The method of claim 17, wherein the second integrated circuit is connected to the first surface and the forming the semiconductor package encapsulates the second integrated circuit chip.

19. The method of claim 17, further comprising:
connecting the semiconductor device to a printed circuit board; and
connecting a third integrated circuit chip to the printed circuit board, the third integrated circuit chip configured to manage the power for the first integrated circuit chip at a first stage, wherein the second integrated circuit chip is configured to manage the power for the first integrated circuit chip at a second stage.

20. The method of claim 17, wherein the second integrated circuit is connected to the second surface and further comprising connecting the semiconductor device to a printed circuit board so that the second surface faces the printed circuit board.
